(19) United States
(12) Patent Application Publication
(10) Pub. No.: US 2026/0255758 A1
(43) Pub. Date: Aug. 27, 2026

(54) DISPLAY DEVICE, ELECTRONIC DEVICE INCLUDING THE SAME, AND METHOD OF MANUFACTURING DISPLAY DEVICE

(71) Applicants: Samsung Display Co., Ltd., Yongin-Si (KR); Research & Business Foundation SUNGKYUNKWAN UNIVERSITY, Suwon-si (KR)

(72) Inventors: JEONGSEOK LEE, Yongin-si (KR); Ji Won SUK, Suwon-si (KR); WOO YONG SUNG, Yongin-si (KR); SEUNGYONG SONG, Yongin-si (KR); Hyeon-Jong LEE, Suwon-si (KR); Soomook LIM, Suwon-si (KR)

(21) Appl. No.: 19/441,599

(22) Filed: Jan. 6, 2026

(30) Foreign Application Priority Data
Feb. 24, 2025 (KR) 10-2025-0023791

(51) Int. Cl. H10H 29/80; H10H 29/01; H10H 29/85

(52) U.S. Cl. CPC H10H 29/842; H10H 29/034; H10H 29/8581

(57) ABSTRACT

A display device includes a display panel and a protective layer directly disposed below the display panel and including a hole which accommodates an electronic module. The protective layer includes a base resin and first particles dispersed in the base resin, each of the first particles includes reduced graphene oxide, and a Young's modulus of the protective layer is in a range from about 4 Gpa to about 50 Gpa.

### CROSS-REFERENCE TO RELATED APPLICATIONS

This application claims priority under 35 U.S.C. § 119 to Korean Patent Application No. 10-2025-0023791, filed on Feb. 24, 2025, the entire contents of which are hereby incorporated by reference.

### BACKGROUND

The present disclosure herein relates to a display device including a lower member of a display device having improved reliability, an electronic device including the display device, and a method of manufacturing the display device.

An electronic device such as a smartphone, digital camera, laptop computer, navigation device (e.g., GPS device), or smart television includes a display device and provides images to users through a display screen.

A display device may include a display panel which provides image information, and a protective layer for protecting the display panel from external environment. For example, the protective layer prevents deformation of the display panel due to an external impact, and effectively dissipates heat generated in the display panel. In order to implement various protective functions to the display panel, the protective layer may have a structure in which a plurality of functional layers are stacked.

Research has been conducted on an electronic device including a protective layer having a single-layer structure with integrated various functions for protecting the display panel is applied, and a method of manufacturing the electronic device.

### SUMMARY

The present disclosure provides a display device in which a single protective layer having improved light output characteristics and improved reliability is disposed below a display panel, and an electronic device including the display device.

The present disclosure also provides a method of manufacturing a display device with improved light output characteristics and reliability.

According to an embodiment of the inventive concept, a display device includes a display panel and a protective layer directly disposed below the display panel and including a hole accommodating an electronic module. The protective layer includes a base resin and first particles dispersed in the base resin, each of the first particles includes reduced graphene oxide, and a Young's modulus of the protective layer is in a range from about 4 Gpa to about 50 Gpa.

In an embodiment, a thermal conductivity of the protective layer may be in a range from about 25 W/mK to about 300 W/mK.

In an embodiment, an average diameter of the first particles may be in a range from about 50 nm to about 250 nm.

In an embodiment, a ratio of a weight of the first particles to a total weight of the protective layer may be in a range from about 0.05 wt % to about 30 wt %.

In an embodiment, the base resin may be a photocurable resin.

In an embodiment, the base resin may include one of solvent-free acryl-based resin, solvent-free urethane-based resin, solvent-free fluorine-based resin, solvent-free epoxy-based resin, solvent-free polyester-based resin, solvent-free polyamide-based resin, and solvent-free silicon-based resin.

In an embodiment, a thickness of the protective layer may be in a range from about 10 μm to about 300 μm.

In an embodiment, the display device may further include a circuit board electrically connected to the display panel, and the protective layer may be in contact with at least a portion of the circuit board.

According to an embodiment of the inventive concept, an electronic device includes a display device including a display panel, a protective layer directly disposed below the display panel and including a hole accommodating an electronic module, and a power module configured to supply power necessary for an operation of the display device. The protective layer includes a base resin and first particles dispersed in the base resin, each of the first particles includes reduced graphene oxide, and a Young's modulus of the protective layer is in a range from about 4 Gpa to about 50 Gpa.

In an embodiment, the display panel may include a first area and a second area adjacent to the first area. The electronic module may overlap the first area and may be disposed below the display panel.

In an embodiment, the protective layer may overlap the second area.

In an embodiment, the hole of the protective layer may be arranged corresponding to the first area, and at least a portion of the electronic module may be disposed inside the hole.

In an embodiment, the electronic module may include a sensor module or a camera module.

According to an embodiment of the inventive concept, a method of manufacturing a display device includes providing a display panel, and forming a protective layer below the display panel. The step of forming the protective layer below the display panel includes preparing a first coating liquid, applying the first coating liquid to a bottom surface of the display panel to form a preliminary protective layer, and curing the preliminary protective layer to form a protective layer. The step of preparing the first coating liquid includes mixing a first solvent with first particles to form a first mixture, mixing the first mixture with a base resin to form a second mixture, and evaporating the first solvent in the second mixture.

In an embodiment, the first solvent may include one of methanol, ethanol, dimethylformamide, dimethylacetamide, N-methylpyrrolidone, and dimethylformamide.

In an embodiment, a dispersity of the first particles in the first solvent may be higher than a dispersity of the first particles in the base resin.

In an embodiment, the step of forming the preliminary protective layer may be performed through an inkjet printing process or a dispenser process.

In an embodiment, the step of curing the preliminary protective layer may include irradiating light onto the preliminary protective layer to photocure the first coating liquid.

In an embodiment, the irradiated light may be ultraviolet light.

In an embodiment, the step of evaporating the first solvent in the second mixture may be performed at a temperature ranging from about 15° C. to about 25° C.

### BRIEF DESCRIPTION OF THE FIGURES

The accompanying drawings are included to provide a further understanding of the inventive concept, and illustrate embodiments of the inventive concept together with the description to explain features of the inventive concept.

FIG. 1A is a block diagram of an electronic device according to an embodiment of the inventive concept.

FIG. 1B is a schematic view of electronic devices according to various embodiments.

FIG. 2 is a perspective view of an electronic device according to an embodiment of the inventive concept.

FIG. 3 is an exploded perspective view of an electronic device according to an embodiment of the inventive concept.

FIG. 4 is a cross-sectional view of an electronic device according to an embodiment of the inventive concept.

FIG. 5 is an enlarged cross-sectional view illustrating a portion of an electronic device according to an embodiment of the inventive concept.

FIG. 6 is an enlarged cross-sectional view illustrating a portion of an electronic device according to an embodiment of the inventive concept.

FIG. 7 is a cross-sectional view of a protective layer according to an embodiment of the inventive concept.

FIG. 8A is a flowchart illustrating a method of manufacturing a display device according to an embodiment of the inventive concept.

FIG. 8B is a flowchart illustrating a step of forming a protective layer in a method of manufacturing a display device according to an embodiment of the inventive concept.

FIG. 8C is a flowchart illustrating a step of preparing a first coating liquid in a method of manufacturing a display device according to an embodiment of the inventive concept.

FIGS. 9A to 9C are cross-sectional views illustrating manufacturing steps of a display device according to an embodiment of the inventive concept.

FIG. 10A illustrates Young's moduli of an embodiment of the inventive concept and a comparative example.

FIG. 10B illustrates thermal conductivities of an embodiment of the inventive concept and a comparative example.

FIG. 11A illustrates photographs of an embodiment of the inventive concept and a comparative example, arranged side by side.

FIG. 11B illustrates photographs of an embodiment of the inventive concept and a comparative example, arranged side-by-side.

### DETAILED DESCRIPTION

The inventive concept may be modified in various forms. Thus, it should be noted that particular embodiments of the inventive concept will be illustrated in the drawings and described herein in detail, and the inventive concept should not be construed as limited to the embodiments set forth herein. Rather, these embodiments are provided to ensure that this disclosure fully conveys the scope of the inventive concept to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or indirectly on, connected to or coupled to the other element with an intervening element disposed therebetween.

Like reference numerals or symbols refer to like elements throughout this specification. In the drawings, the thickness, ratio, and size of the elements are exaggerated for effectively describing the technical features of the inventive concept. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be referred to as a second element without departing from the scope of the inventive concept. Similarly, a second element could be referred to as a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the spatial relation between elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an electronic device according to an embodiment will be described with reference to the accompanying drawings.

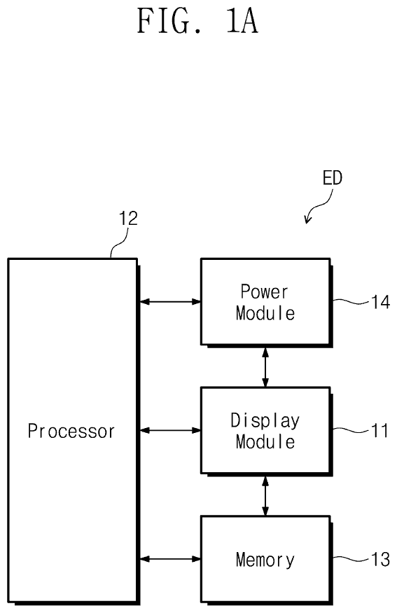

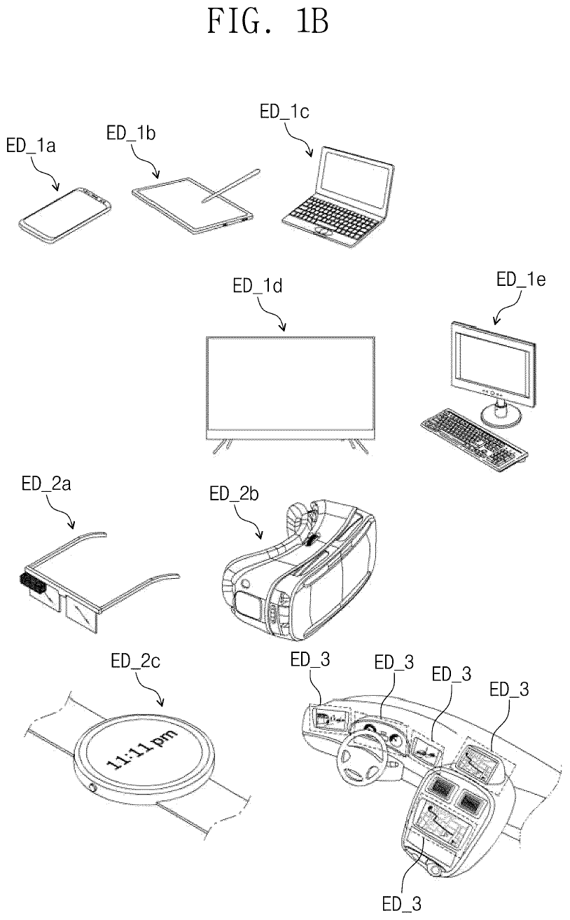

FIG. 1A is a block diagram of an electronic device according to an embodiment. Referring to FIG. 1A, an electronic device ED according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information necessary for an operation of the processor 12 or the display module 11. When the processor 12 executes an application stored in the memory 15, an image data signal and/or an input control signal may be transmitted to the display module 11, and the display module 11 may process the received signal, and output image information through a display screen.

The power module 14 may include a power supply module such as a power adapter or a battery device, and a power conversion module which converts power supplied from the power supply module and generates power necessary for an operation of the electronic device ED.

At least one of the components of the electronic device ED described above may be included in the display device according to an embodiment described below. In addition, some of individual modules included in one module may be incorporated into the display device, and others may be provided separately from the display device. For example, while the display device may include the display module 11, the processor 12, the memory 13 and the power module 14 may not be included in the display device but may be implemented as another type of component within the electronic device ED.

FIG. 1B is a schematic view of electronic devices according to various embodiments.

Referring to FIG. 1B, various electronic devices to which the display device according to an embodiment is applied may include not only an electronic device for displaying image, e.g., a smartphone ED_1a, a tablet PC ED_1b, a laptop computer ED_1c, TV ED_1d, and a monitor for a desk computer ED_1e, but also a wearable electronic device including a display module, e.g., smart glasses ED_2a, a head mounted display ED_2b, and a smart watch ED_2c, and a vehicle electronic device ED_3 including a display module, e.g., a vehicle instrument panel, a center fascia, a center information display (CID) disposed on a dashboard, and a room mirror display. These are just provided as examples, and the display device may be applied to other electronic devices unless departing from the inventive concept.

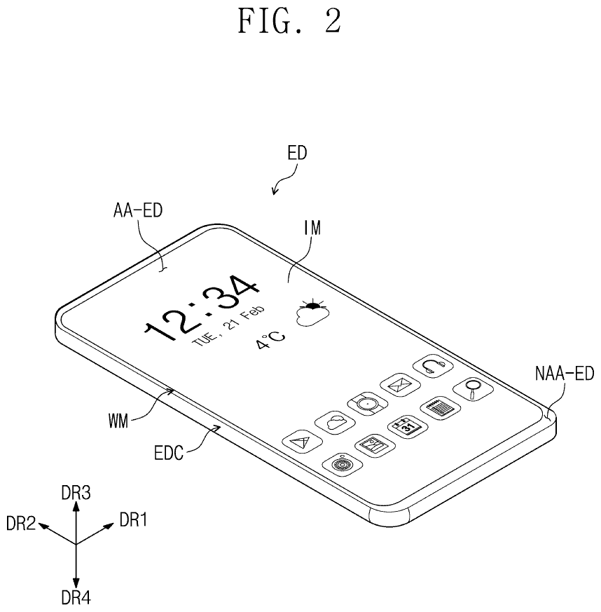

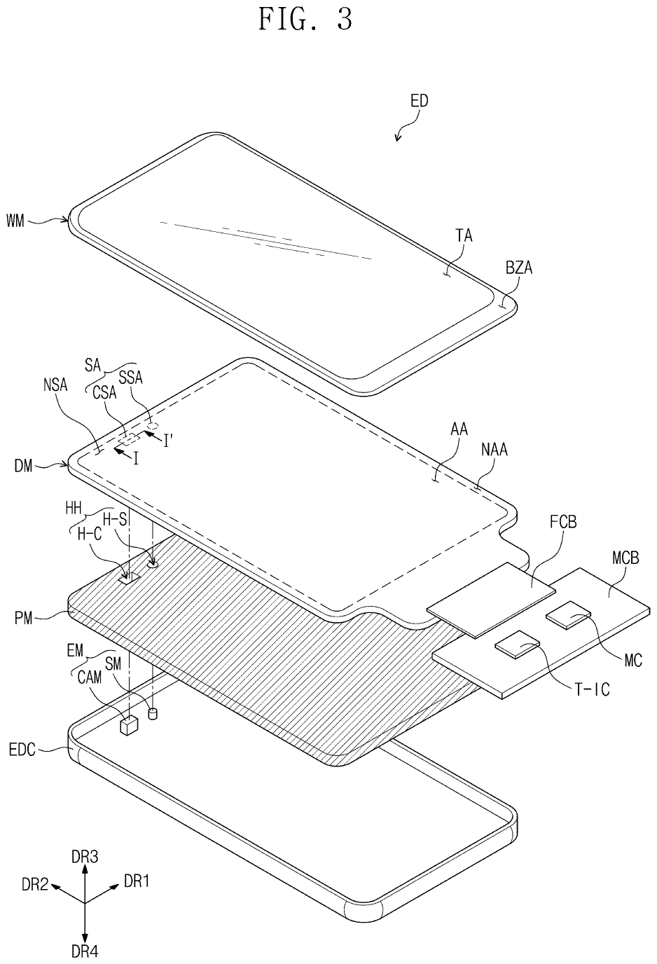

FIG. 2 is an assembled perspective view of an electronic device according to an embodiment of the inventive concept. FIG. 3 is an exploded perspective view of an electronic device according to an embodiment of the inventive concept. As an example, FIGS. 2 and 3 illustrate one of the electronic devices for displaying image, illustrated in FIG. 1B, such as the smartphone ED_1a, the tablet PC ED_1b, the laptop computer ED_1c, the TV ED_1d, and the monitor for a desk computer ED_1e, but the electronic device that the inventive concept is applied to is not limited to the illustrated type.

Referring to FIG. 3, an electronic device ED may be a device that is activated in response to an electrical signal and displays an image. For example, the electronic device ED may be a large-sized device such as television or outdoor billboard, and may also be a small and medium-sized device such as monitor, mobile phone, tablet computer, navigation device, game console. However, the embodiments of the electronic device ED are examples, and the electronic device ED of the inventive concept is not limited to any one of the examples above as long as the exemplified electronic device ED does not depart from the technical feature of the inventive concept.

The electronic device ED may be rigid or flexible. The term “flexible” means a characteristic of being capable of bending. For example, the flexible electronic device ED may include a curved device, a rollable device, or a foldable device.

FIG. 2 and subsequent figures illustrate a first directional axis DR1 to a fourth directional axis DR4, and directions indicated by first to fourth directional axis DR1, DR2, DR3 and DR4 used herein are relative concepts and may be changed to other directions. The directions indicated by the first to fourth directional axis DR1, DR2, DR3 and DR4 may be also referred to as first to fourth directions DR1, DR2, DR3 and DR4, and may be designated by like reference numbers or symbols. As used herein, the first directional axis DR1 and the second directional axis DR2 perpendicularly cross each other, and each of the third directional axis DR3 and the fourth directional axis DR4 may be a normal direction to a plane defined by the first directional axis DR1 and the second directional axis DR2.

A thickness direction of the electronic device ED may be a direction parallel to the third directional axis DR3 that is a normal direction to a plane defined by the first directional axis DR1 and the second directional axis DR2. The electronic device ED may provide the image IM to a user through a display surface. As used herein, a front surface (or top surface) and a rear surface (or bottom surface) of each component are defined on the basis of a direction in which the image IM is displayed. As used herein, the direction in which the image IM is displayed may be referred to as a direction of the third directional axis DR3, and a direction of the fourth directional axis DR4 may be referred to as a direction opposing to the third directional axis DR3.

As used herein, the term “on a plane” may be referred to as a state when viewed in the third direction DR3. The term “on a cross-section” used herein may be referred to as a state when viewed in the first direction DR1 or the second direction DR2. Directions indicated by the first to fourth directions DR1, DR2, DR3 and DR4 are relative concepts and may be changed to other directions.

Referring to FIG. 2, the electronic device ED according to an embodiment may display the image IM through an active area AA-ED. The active area AA-ED may include a flat surface defined by the first direction DR1 and the second direction DR2. The active area AA-ED may further include a curved surface which is bent from at least one side of the flat surface defined by the first direction DR1 and the second direction DR2. A surface on which the image IM is displayed may correspond to a front surface of the electronic device ED. The image IM may include not only a dynamic image but also a still image.

A peripheral area NAA-ED is adjacent to the active area AA-ED. The peripheral area NAA-ED may surround at least one side of the active area AA-ED. Accordingly, a shape of the active area AA-ED may be substantially same as or similar to a space defined by the peripheral area NAA-ED. However, this is illustrated as an example, and the peripheral area NAA-ED may be disposed adjacent to only one side of the active area AA-ED or may be omitted. The electronic device ED according to an embodiment of the inventive concept may include active areas having various shapes, and is not limited to any one embodiment.

The electronic device ED may have a rectangular shape which has short sides extending in the first direction DR1 on a plane and has long sides extending in the second direction DR2 crossing the first direction DR1 on a plane. However, an embodiment of the inventive concept is not limited thereto, and the electronic device ED may have various shapes, such as a circular shape or a polygonal shape, on a plane.

Although not illustrated, the electronic device ED according to an embodiment may be a flexible device. At least a portion of the electronic device ED according to an embodiment may be bent. For example, the electronic device ED according to an embodiment may be a flexible device which is capable of variably changing the shape between a folded state and an unfolded state with respect to at least one folding axis extending in one direction.

The electronic device ED according to an embodiment may detect an external input applied from the outside. The external input may include various types of inputs such as power, pressure, temperature, and light.

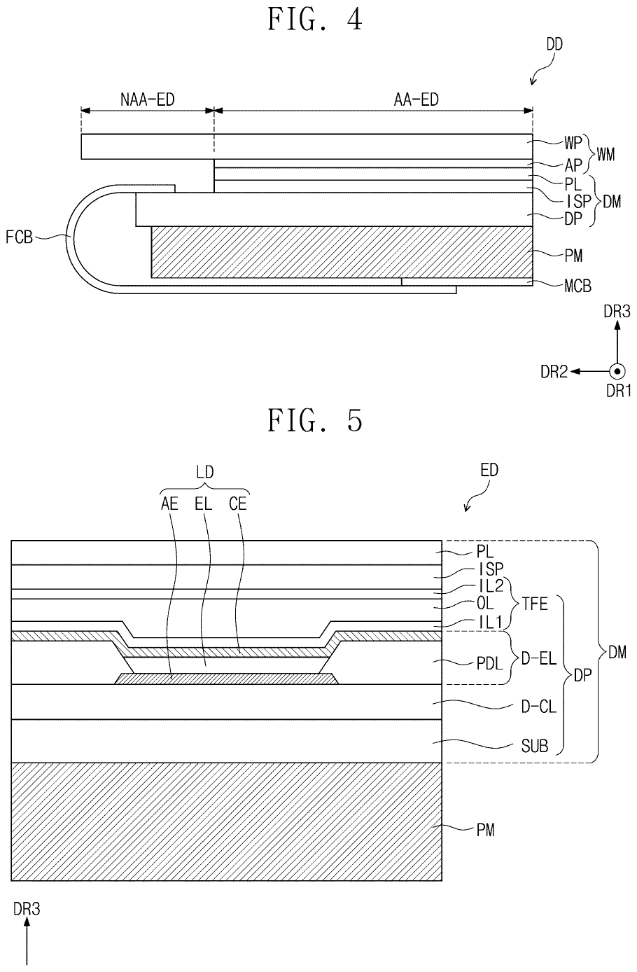

FIG. 3 is an exploded perspective view of an electronic device according to an embodiment of the inventive concept. FIG. 4 is a cross-sectional view of an electronic device according to an embodiment of the inventive concept. FIG. 4 illustrates an enlarged cross-section of a portion of an electronic device ED according to an embodiment of the inventive concept.

Referring to FIGS. 3 and 4, the electronic device ED may include a window module WM, a display device DD, and a housing EDC. The display device DD according to an embodiment may include a display module DM and a protective layer PM disposed below the display module DM.

The display module DM may be a component which displays an image and detects an input applied from the outside. The display module DM according to an embodiment may include a display panel DP and an input sensor ISP disposed on the display panel DP. In addition, the display module DM according to an embodiment may further include an optical layer PL disposed on the input sensor ISP.

An active area AA and a peripheral area NAA may be defined in the display module DM according to an embodiment. The active area AA may be an area that is activated in response to an electrical signal and displays images. The peripheral area NAA may be an area that is disposed adjacent to at least one side of the active area AA.

The active area AA may correspond to the active area AA-ED of the electronic device ED illustrated in FIG. 3. The peripheral area NAA may be arranged to surround at least one side of the active area AA. However, an embodiment is not limited thereto, and a portion of the peripheral area NAA may be omitted in an embodiment. The peripheral area NAA may correspond to the peripheral area NAA-ED of the electronic device ED illustrated in FIG. 3.

The display module DM according to an embodiment may include the peripheral area NAA disposed on at least one side of the active area AA. The peripheral area NAA may include a driving circuit, a driving line, or the like for driving the active area AA.

The display module DM may include a first area SA and a second area NSA. The active area AA of the display module DM may include the first area SA and the second area NSA. The first area SA may be an area overlapping an electronic module EM, and the second area NSA may be an area surrounding at least a portion of the first area SA. On a plane, a surface area of the first area SA may be less than a surface area of the second area NSA.

The second area NSA and the first area SA may have different transmittances. The transmittance of the first area SA may be higher than the transmittance of the second area NSA. In the display module DM according to an embodiment, a portion of a driving circuit, a driving line, or the like for driving pixels disposed in the first area SA may be disposed in the peripheral area NAA or in a portion of the second area NSA adjacent to the first area SA. Thus, a wiring density in the first area SA may be lower than a wiring density in the second area NSA. However, an embodiment is not limited thereto, and the wiring density in the first area SA and the wiring density in the second area NSA may be substantially the same.

The electronic module EM may overlap the first area SA. The electronic module EM may receive an external input transmitted through the first area SA or provide an output through the first area SA. The first area SA may include a first signal transmission area CSA corresponding to a camera sensing area CSA-ED of the electronic device ED, and a second signal transmission area SSA corresponding to a sensor sensing area SSA-ED of the electronic device ED. A camera module CAM may overlap the first signal transmission area CSA, and a sensor module SM may overlap the second signal transmission area SSA.

Although not illustrated, a certain opening portion may be defined in a portion of the first area SA of the display module DM when necessary. That is, a portion of the first area SA of the display module DM, which corresponds to the first signal transmission area CSA overlapping the camera module CAM, may be penetrated.

FIG. 3 illustrates an example in which the first area SA includes the first signal transmission area CSA and the second signal transmission area SSA, i.e., two transmission areas, but the number of transmission areas in the first area SA is not limited thereto. For example, a plurality of transmission areas may be defined in the first area SA of the display module DM. In addition, FIG. 3 illustrates an example in which the first area SA has a circular or polygonal shape. However, the shape of the first area SA is not limited thereto, and may be variously defined as necessary.

The display panel DP according to an embodiment may be a component that substantially generates an image. The display panel DP may be an emissive display panel. For example, the display panel DP may be an organic light emitting display panel, an inorganic light emitting display panel, a quantum dot display panel, a micro LED display panel, or a nano LED display panel. The display panel DP may be referred to as a display layer.

The display module DM may further include the optical layer PL disposed above the display panel DP. The optical layer PL may be disposed on the input sensor ISP. The optical layer PL may be a reflection reducing layer that reduces reflectance of external light incident from the outside of the display module DM. The optical layer PL may be formed on the input sensor ISP through a continuous process. In an embodiment, the optical layer PL may include a polarizing layer.

For example, the optical layer PL may include a polarizing layer which includes a retarder and/or a polarizer, a plurality of reflective layers which reduces reflected light by destructive interference between each of the plurality of reflective layers, or color filters which are arranged to correspond to the arrangements of the pixels or the emissive colors of the pixels in the display panel DP. For example, when the optical layer PL includes color filters, the color filters may be arranged in a space corresponding to light of emissive colors from the pixels included in the display panel DP. However, the inventive concept is not limited thereto. For example, the optical layer PL may be omitted in an embodiment.

The display module DM may further include a circuit board. The display module DM may further include a main circuit board MCB, a flexible circuit film FCB, a sensor control circuit T-IC, and a main controller MC.

The main circuit board MCB may be electrically connected to the display module DM through the flexible circuit film FCB. The main circuit board MCB may be electrically connected to the electronic module EM through a connector.

The flexible circuit film FCB may be connected to each of the display panel DP and the input sensor ISP and electrically connect the display panel DP and the input sensor ISP to the main circuit board MCB. The input sensor ISP may be electrically connected to the display panel DP and thus electrically connected to the main circuit board MCB through the flexible circuit film FCB. However, an embodiment is not limited thereto, and the input sensor ISP may be electrically connected to the main circuit board MCB through an additional flexible circuit film. However, the inventive concept is not limited thereto. For example, the flexible circuit film FCB may be omitted and the main circuit board MCB may be directly connected onto the display panel DP.

In the display module DM according to an embodiment, the flexible circuit film FCB may be in a bent state and be disposed under the display module DM. For example, the flexible circuit film FCB may be bent toward a rear surface of the display panel DP and be disposed below the protective layer PM. The protective layer PM may be in contact with the flexible circuit film FCB or the main circuit board MCB. In an embodiment, the flexible circuit film FCB may be assembled in the bent state, and the protective layer PM may be in contact with the flexible circuit film FCB. However, an embodiment of the inventive concept is not limited thereto.

Each of the sensor control circuit T-IC and the main controller MC may be provided in the form of an integrated chip. The sensor control circuit T-IC and the main controller MC may be mounted on the main circuit board MCB. However, an embodiment is not limited thereto.

The main controller MC may control an overall operation of the electronic device ED. For example, the main controller MC may control an operation of each of the display panel DP and the input sensor ISP. In addition, the main controller MC may control an operation of the electronic module EM. The main controller MC may include at least one microprocessor.

Although not illustrated, the display module DM may include a data driver (not illustrated) including a driving circuit for driving the pixels in the display panel DP. The data driver (not illustrated) may receive image data and a control signal from the processor 12 through the main controller MC. For example, the control signal may include an input vertical synchronization signal, an input horizontal synchronization signal, a main clock, a data enable signal, and the like. However, the inventive concept is not limited thereto. For example, the data driver (not illustrated) may be directly disposed in the peripheral area NAA of the display panel DP.

The sensor control circuit T-IC may provide the input sensor ISP with an electrical signal for driving the input sensor ISP. The sensor control circuit T-IC may receive a control signal, such as a clock signal, from the processor 12 through the main controller MC.

The electronic module EM may include various functional modules necessary for driving the electronic device ED. For convenience of description, the camera module CAM and the sensor module SM are illustrated as examples of the electronic module EM that are disposed in a space corresponding to the first area SA of the display module DM in FIG. 3. However, the number of or the types of the electronic module EM is not limited thereto, and the electronic module EM according to the inventive concept may include various other types of functional modules. The modules of the electronic module EM may be mounted on the main circuit board MCB, or be electrically connected to the main circuit board MCB through a separate flexible circuit board.

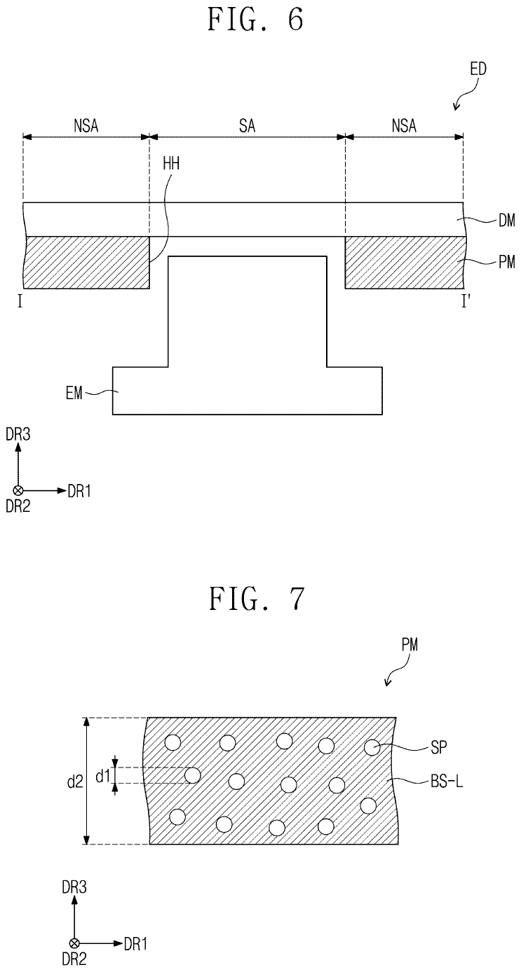

The protective layer PM may be disposed below the display module DM. The protective layer PM may be a member which supports the display module DM, absorbs an impact applied to the display module DM, and performs a heat dissipation function by releasing heat generated from the components, for example, the electronic module EM and the like, disposed below the display module DM. The protective layer PM will be described later in detail with reference to FIG. 6 and subsequent figures.

The window module WM may be disposed on the display module DM and protect the display module DM from external impacts or scratches. The window module WM may cover the entire outside of the display module DM. A front surface of the window module WM may correspond to a top surface of the electronic device ED.

In an embodiment, the window module WM may include a base substrate WP that is an optically transparent insulating material. The base substrate WP may include an optically transparent insulating material. The base substrate WP may include at least one of a glass substrate or a synthetic resin film. The base substrate WP may have a single-layer structure, or have a multilayer structure in which a plurality of films are coupled to each other. The window module WM may further include a functional layer such as an anti-fingerprint layer, a phase control layer, or a hard coating layer, disposed on the base substrate WP.

The window module WM may further include an adhesive layer AP. The base substrate WP and the display module DM may be coupled to each other through the adhesive layer AP. However, an embodiment of the inventive concept is not limited thereto. For example, the adhesive layer AP may be omitted and the window module WM may be directly disposed on the display module DM.

The window module WM may be divided into a transmission part TA and a bezel part BZA. The transmission part TA may be a portion corresponding to the active area AA of the display module DM, and the bezel part BZA may be a portion corresponding to the peripheral area NA of the display module DM. The bezel part BZA may define a shape of the transmission part TA. The bezel part BZA may be adjacent to the transmission part TA and surround at least one side of the transmission part TA. However, an embodiment of the inventive concept is not limited to the illustrated shape. For example, the bezel part BZA may be disposed adjacent to only one side of the transmission part TA, or a portion of the bezel part BZA may be omitted.

The window module WM and the housing EDC may be coupled to each other and form an outer appearance of the electronic device ED. The window module WM and the housing EDC may be coupled to define an inner space which accommodates the components of the electronic device ED. The display module DM, the flexible circuit film FCB, the main circuit board MCB, the electronic module EM, and the like may be accommodated in the inner space. A portion of the display module DM may be accommodated in the housing EDC by being bent so that the flexible circuit film FCB and the main circuit board MCB face the rear surface of the display module DM.

The housing EDC may include a material having relatively high rigidity. For example, the housing EDC may include glass, plastic, or metal, or include a frame and/or a plate each including a combination thereof. The housing EDC may absorb an impact applied from the outside or prevent penetration of foreign matter/moisture and the like from the outside, thereby protecting the display module DM and the components of the electronic device ED accommodated in the housing EDC.

FIG. 5 is an enlarged cross-sectional view illustrating a portion of an electronic device according to an embodiment of the inventive concept. FIG. 5 illustrates the configuration of a display module DM in more detail. As an example, FIG. 5 illustrates only one light emitting element disposed in the active area AA (see FIG. 3) and a peripheral portion thereof. The configuration of the light emitting element as illustrated in FIG. 5 may apply to other light emitting elements disposed in the active area AA (see FIG. 3) and peripheral portions thereof.

In an embodiment, the display module DM includes a display panel DP, an input sensor ISP, and an optical layer PL. The display panel DP includes a base layer SUB, a circuit layer D-CL, a display element layer D-EL, and an encapsulation layer TFE. In an embodiment, a protective layer PM may be disposed below the base layer SUB. The protective layer PM may be directly disposed below the base layer SUB.

The base layer SUB may be a member which provides a base surface on which the circuit layer D-CL is disposed. The base layer SUB may be a rigid substrate, or a flexible substrate capable of bending, folding, rolling, or the like. The base layer SUB may be a glass substrate, a metal substrate, a polymer substrate, or the like. However, an embodiment of the inventive concept is not limited thereto, and the base layer SUB may be an inorganic layer, an organic layer, or a composite material layer. In an embodiment of the inventive concept, the base layer SUB may include a flexible polymer film. For example, the base layer SUB according to an embodiment may include a flexible polyimide film.

The circuit layer D-CL may be disposed on the base layer SUB. The circuit layer D-CL may include a plurality of insulating layers, a plurality of transistors, a conductive pattern, a signal line, and the like. In an embodiment, a plurality of inorganic films, a plurality of organic films, a semiconductor layer, and a conductive layer may be formed using a method such as coating or deposition. Thereafter, the inorganic films, the organic films, the semiconductor layer, and the conductive layer may be selectively patterned using a photolithography method. In this way, the circuit layer D-CL may be formed to include the plurality of insulating layers which include the inorganic films and/or the organic films, the plurality of transistors including a semiconductor pattern made from the semiconductor layer, the conductive pattern and the signal line made from the conductive layer, and the like. In FIG. 5, although the configuration of the circuit layer D-CL is illustrated briefly, it is noted that the plurality of transistors and the signal line of the circuit layer D-CL may be electrically connected to a light emitting element LD of the display element layer D-EL.

The display element layer D-EL may be provided on the circuit layer D-CL, and the encapsulation layer TFE may be provided on the display element layer D-EL to cover the display element layer D-EL.

The display element layer D-EL may include a pixel defining film PDL and the light emitting element LD. The light emitting element LD may include a first electrode AE, a light emitting layer EL, and a second electrode CE.

The first electrode AE may be referred to as a pixel electrode. The first electrode AE may include a metal material, a metal alloy, or a conductive compound. The first electrode AE may be an anode or a cathode. The first electrode AE may be a transmissive electrode, a semi-transmissive electrode, or a reflective electrode. When the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), or the like. When the first electrode AE is the semi-transmissive electrode or the reflective electrode, the first electrode AE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg). However, an embodiment of the inventive concept is not limited thereto. For example, the first electrode AE may have a multilayer structure including a reflective film or a semi-transmissive film, each of which includes the foregoing material, and a transmissive conductive film which includes indium tin oxide (ITO), indium zinc oxide (IZO), zinc oxide (ZnO), indium tin zinc oxide (ITZO) or the like. For example, the first electrode AE may have a three-layer structure of ITO/Ag/ITO, but the structure of the first electrode AE is not limited thereto. For example, the first electrode AE may include the foregoing metal material, a combination of two or more metal materials selected from the foregoing metal materials, an oxide of the foregoing metal materials, or the like.

The pixel defining film PDL may be disposed on the circuit layer D-CL. In an embodiment, the pixel defining film PDL may include a polymer resin. For example, the pixel defining film PDL may include an organic material such as a polyacrylate-based resin or a polyimide-based resin. For example, the pixel defining film PDL may include an inorganic material. The pixel defining film PDL may include a light absorbing material, or include a black pigment or a black dye. When the pixel defining film PDL includes the black pigment or the black dye, the pixel defining film PDL may become a black pixel defining film. In the formation of the pixel defining film PDL, a carbon black or the like may be used as the black pigment or the black dye, but an embodiment is not limited thereto.

In addition, the pixel defining film PDL may include an inorganic material. For example, the pixel defining film PDL may include a silicon nitride, a silicon oxide, a silicon oxynitride, or the like.

A pixel opening portion which extends to a portion of the first electrode AE may be defined in the pixel defining film PDL. In the display module DM according to an embodiment, emission areas may be defined by the pixel defining film PDL. For example, each of the emission areas in the display module DM may be a portion corresponding to the pixel opening portion where the light emitting layer EL is disposed on the first electrode AE which is not covered by the pixel defining film PDL.

In the light emitting element LD, the light emitting layer EL may be disposed on the first electrode AE. In an embodiment of the inventive concept, the light emitting layer EL may emit light having at least one of a blue color, a red color, and a green color. However, an embodiment of the inventive concept is not limited thereto. For example, the light emitting layer EL may provide light of a blue color throughout the active area AA (see FIG. 3). In this case, the display module DM (see FIG. 3) may further include a component of a light control part which converts a wavelength of light emitted from the light emitting element LD. For example, the light control part of the display module DM may convert the blue light into the red light or the green light.

The second electrode CE may be disposed on the light emitting layer EL. The second electrode CE may have an integral shape and may be commonly disposed in the plurality of light emitting elements arranged in the active area AA (see FIG. 2). The second electrode CE may be referred to as a common electrode. The second electrode CE may be a cathode or an anode. For example, when the first electrode AE is an anode, the second electrode CE may be a cathode. In contrast, when the first electrode AE is a cathode, the second electrode CE may be an anode.

The second electrode CE may be a transmissive electrode, a semi-transmissive electrode, or a reflective electrode. When the second electrode CE is a transmissive electrode, the second electrode CE may include a transparent metal oxide, for example, indium tin oxide (ITO), indium zinc oxide (IZO), zinc oxide (ZnO), indium tin zinc oxide (ITZO), or the like. However, an embodiment of the inventive concept is not limited thereto. For example, the second electrode CE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg).

Although not illustrated, a hole control layer may be disposed between the first electrode AE and the light emitting layer EL. The hole control layer may include a hole transport layer, and further include a hole injection layer. An electron control layer may be disposed between the light emitting layer EL and the second electrode CE. The electron control layer may include an electron transport layer, and further include an electron injection layer. The hole control layer and the electron control layer may be provided, in common, in the plurality of light emitting elements throughout the active area AA (see FIG. 3) by using an open mask.

The encapsulation layer TFE may be disposed on the display element layer D-EL. The encapsulation layer TFE may include a first inorganic layer IL1, an organic layer OL, and a second inorganic layer IL2 which are stacked in sequence. However, the layers which are included in the encapsulation layer TFE are not limited to the layers exemplified above.

The inorganic layers IL1 and IL2 may protect the display element layer D-EL from moisture and oxygen, and the organic layer OL may protect the display element layer D-EL from foreign matter such as dust particles. Each of the inorganic layers IL1 and IL2 may include at least one of silicon nitride, silicon oxynitride, silicon oxide, titanium oxide, and aluminum oxide. The organic layer OL may include an organic layer such as an acryl-based organic material. However, the types of the materials which form the inorganic layers IL1 and IL2 and the organic layer OL are not limited thereto.

The input sensor ISP may be disposed on the encapsulation layer TFE. In an embodiment, the input sensor ISP may include insulating layers and a sensor conductive layer. In an embodiment, the input sensor ISP may be directly disposed on the encapsulation layer TFE.

The display module DM according to an embodiment may include the optical member PL. In an embodiment, the optical layer PL may be directly disposed on the input sensor ISP. However, an embodiment is not limited thereto, and an adhesive layer or the like may be further included between the optical layer PL and the input sensor ISP. The optical layer PL may be a reflection reducing layer that reduces external light. The embodiment of the inventive concept is not limited thereto, and the optical layer PL may be omitted.

FIG. 6 is an enlarged cross-sectional view illustrating a portion of an electronic device according to an embodiment of the inventive concept. FIG. 6 is a cross-sectional view illustrating a portion of an electronic device according to an embodiment corresponding to a cutting line I-I′ illustrated in in FIG. 3. FIG. 6 illustrates a first area SA of an electronic device ED in more detail. FIG. 7 is a cross-sectional view of a protective layer according to an embodiment of the inventive concept. In order to show a protective layer PM illustrated in FIG. 6 in more detail, FIG. 7 illustrates an enlarged cross-sectional view of a portion of the protective layer PM.

Referring to FIGS. 6 and 7, the electronic device ED according to an embodiment of the inventive concept may include a display module DM, the protective layer PM, and an electronic module EM.

The protective layer PM according to an embodiment of the inventive concept is disposed below the display module DM. The protective layer PM is directly disposed below the display panel DP (see FIG. 5). A separate adhesive member may not be disposed between the protective layer PM and the display panel DP (see FIG. 5).

The protective layer PM may not overlap the first area SA but overlap a second area NSA on a plane. The protective layer PM may correspond to the second area NSA of the display module DM. The protective layer PM may be disposed below the display module DM so as to overlap the second area NSA. The protective layer PM may include a hole HH. The hole HH may define a space which accommodates the electronic module EM. The hole HH of the protective layer PM may not overlap the first area SA of the display panel DP. The electronic module EM according to an embodiment is accommodated in a space defined by the hole HH such that the electronic module EM may overlap the first area SA of the display module DM through the hole HH. At least a portion of the electronic module EM may be arranged in the space defined by the hole HH. For example, the electronic module EM may be the camera module CAM (see FIG. 2) including a lens, and the lens of the camera module CAM (see FIG. 2) may be inserted into and disposed within the hole HH.

The protective layer PM may include a base resin BS-L and a plurality of first particles SP, thereby performing multiple functions in the electronic device. For example, the protective layer PM may support the display module DM. The protective layer PM may protect the display panel DP or the like from physical impacts applied from the outside of the electronic device ED. The protective layer PM may perform a heat dissipation function by releasing heat generated from the display module DM or the like. The protective layer PM may also have a function such as electromagnetic wave shielding. However, an embodiment of the inventive concept is not limited thereto. For example, according to the properties such as thickness and materials of the protective layer PM, the protective layer PM may further perform additional functions in the electronic device ED. In the electronic device ED according to an embodiment, since the protective layer PM having a single-layer structure simultaneously performs the multiple functions such as impact absorption and heat dissipation, the thickness of the electronic device ED may be reduced, components may be simplified, and process efficiency may be improved during the manufacture of the electronic device ED.

The protective layer PM includes the base resin BS-L and the first particles SP dispersed in the base resin BS-L. The protective layer PM may be a single layer including the base resin BS-L and the plurality of first particles SP. The plurality of first particles SP may be fillers dispersed in the base resin BS-L.

The base resin BS-L may include a solvent-free resin. The base resin BS-L may include at least one of solvent-free acryl-based resin, solvent-free urethane-based resin, solvent-free fluorine-based resin, solvent-free epoxy-based resin, solvent-free polyester-based resin, solvent-free polyamide-based resin, and solvent-free silicon-based resin. The base resin BS-L may include a curable resin. For example, the base resin BS-L may include a UV photocurable resin.

Each of the plurality of first particles SP may include a reduced graphene oxide material. Each of the plurality of first particles SP may include reduced graphene oxide. An amount of the plurality of first particles SP in the whole material included in the protective layer PM may be about 0.05 wt % to about 30 wt %. For example, the amount of the plurality of first particles SP in the whole material included in the protective layer PM may be about 0.05 wt % to about 10 wt %.

An average diameter d1 of the plurality of first particles SP may be about 5 nm to about 1000 nm. The average diameter d1 of the plurality of first particles SP may be about 50 nm to about 250 nm. For example, the average diameter d1 of the plurality of first particles SP may be about 90 nm to about 120 nm. Accordingly, the degree to which the first particles SP are dispersed in the base resin BS-L may be relatively high in the protective layer PM, and optical characteristics of the protective layer PM including the first particles SP may be improved. FIG. 7 illustrates an example in which the first particles SP has the same diameter, but an embodiment of the inventive concept is not limited thereto. For example, each size of the first particles SP may be substantially the same as each other (in other words, the first particles SP may have a monodisperse distribution), or some of the first particles SP may have different sizes from the other first particles SP (in other words, the first particles may have a polydisperse distribution).

A Young's modulus of the protective layer PM may be about 4 Gpa to about 50 Gpa. For example, the Young's modulus of the protective layer PM may be about 4 Gpa to about 10 Gpa. A thermal conductivity of the protective layer PM may be about 25 W/mK to about 300 W/mK. For example, the thermal conductivity of the protective layer PM may be about 25 W/mK to about 100 W/mK. Accordingly, even when the protective layer PM has a single-layer structure disposed below the display panel DP, the protective layer PM may perform the multiple functions such as supporting the display module DM, dissipating heat, and shielding and protecting the display module DM, thereby improving the reliability of the display module DM.

A thickness d2 of the protective layer PM may be about 10 μm to about 300 μm. For example, the thickness d2 of the protective layer PM may be about 40 μm to about 150 μm. As the average diameter d1 of the first particles SP included in the protective layer PM is about 50 nm to about 250 nm, the thickness d2 of the protective layer PM may be implemented to have a relatively thin thickness. Since the electronic device ED according to an embodiment of the inventive concept may include the protective layer PM having a relatively thin thickness, bending or folding characteristics of the electronic device ED may be improved.

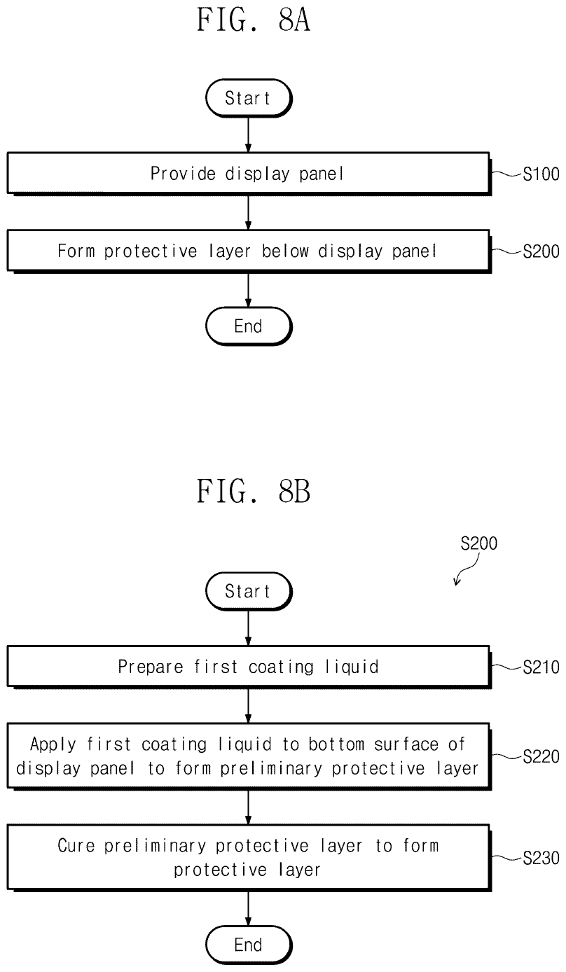

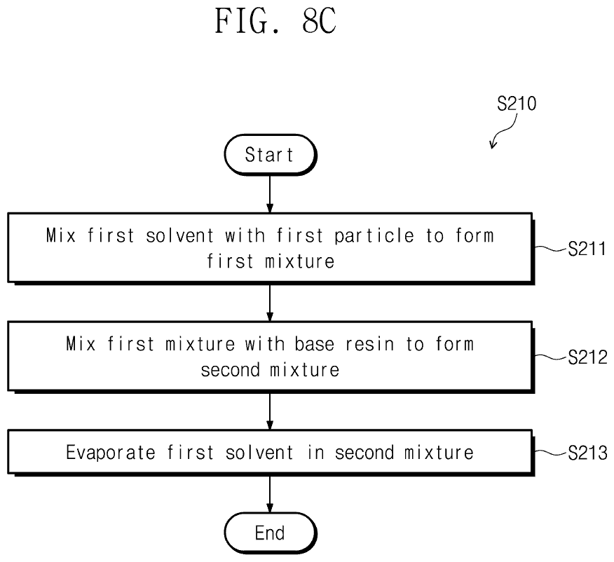

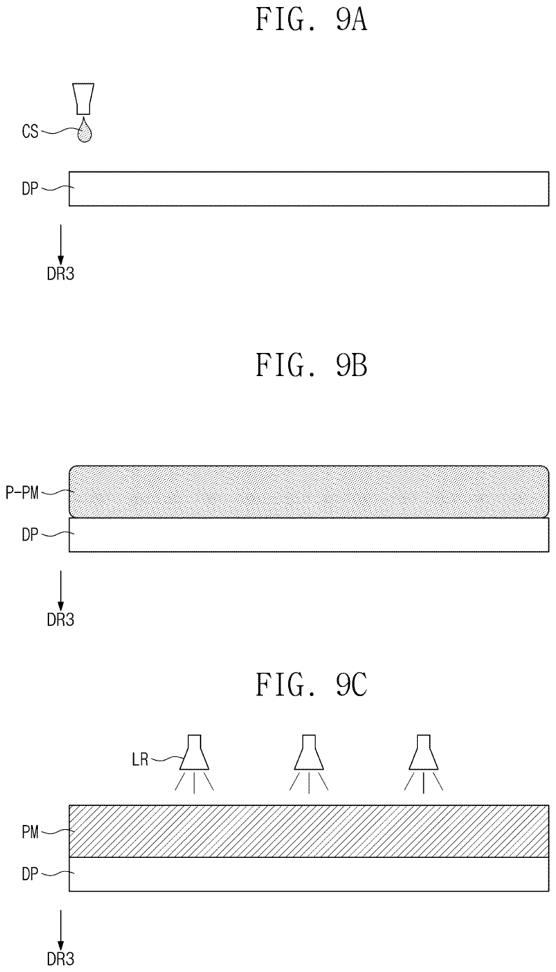

FIG. 8A is a flowchart illustrating a method of manufacturing a display device according to an embodiment of the inventive concept. FIG. 8B is a flowchart illustrating a step of forming a protective layer in a method of manufacturing a display device according to an embodiment of the inventive concept. FIG. 8C is a flowchart illustrating a step of preparing a first coating liquid in a method of manufacturing a display device according to an embodiment of the inventive concept. FIGS. 9A to 9C are cross-sectional views illustrating manufacturing steps of a display device according to an embodiment of the inventive concept. The method of manufacturing the display device according to an embodiment of the inventive concept may be a method of manufacturing the display device DD according to an embodiment described with reference to FIGS. 1 to 6. Hereinafter, the method of manufacturing the display device according to an embodiment will be described with reference to FIGS. 8A to 8C, and 9A to 9C. Hereinafter, components which are same as or similar to components described above with reference to FIGS. 1 to 7 will be designated using the same or similar reference characters, and the repetitive description will be omitted.

Referring to FIG. 8A, the method of manufacturing the display device according to an embodiment of the inventive concept includes providing a display panel (S100) and forming a protective layer below the display panel (S200).

Referring to FIG. 8B, the step of forming the protective layer (S200) according to an embodiment of the inventive concept includes preparing a first coating liquid (S210), applying the first coating liquid to a bottom surface of the display panel to form a preliminary protective layer (S220), and curing the preliminary protective layer to form a protective layer (S230).

Referring to FIGS. 8B and 8C, the step of forming the protective layer (S200) according to an embodiment of the inventive concept includes the step of preparing the first coating liquid (S210). The step of preparing the first coating liquid (S210) includes mixing a first solvent with first particles to form a first mixture (S211), mixing the first mixture with a base resin to form a second mixture (S212), and evaporating the first solvent in the second mixture (S213).

The step of preparing the first coating liquid (S210) may include the step of forming the first mixture (S211) by mixing the first solvent with the first particles. The first solvent may include methanol, ethanol, dimethylformamide, dimethylacetamide, N-methylpyrrolidone, dimethylformamide, or a compound or mixture thereof. The first particles may include a reduced graphene oxide material. Accordingly, the solubility of the first particles in the first solvent may be relatively high.

The step of preparing the first coating liquid (S210) may include the step of forming the second mixture (S212) by mixing the first mixture with the base resin. The step of mixing the first mixture with the base resin may be performed using a high shear mixer. The base resin may contain no solvent. The base resin may be a UV photocurable resin. The base resin may include at least one of acryl-based resin, urethane-based resin, fluorine-based resin, epoxy-based resin, polyester-based resin, polyamide-based resin, and silicon-based resin. The solubility of the first particles in the first solvent may be relatively higher than a solubility of the first particles in the base resin. That is, the first solvent may be provided to disperse the first particles in the base resin.

The step of preparing the first coating liquid (S210) may include the step of evaporating the first solvent in the second mixture (S212). The step of evaporating the first solvent may be performed at a temperature from about 15° C. to about 25° C. The first solvent may be a solvent having volatility at a temperature from about 15° C. to about 25° C. However, an embodiment of the inventive concept is not limited thereto, and any step for dispersing the first particles in the base resin may be adopted without limitation.

Referring to FIGS. 8B and 9A to 9C, the step of forming the protective layer according to an embodiment of the inventive concept (S200) includes applying a first coating liquid CS prepared by the foregoing method to a bottom surface of a display panel DP to form a preliminary protective layer P-PM (S220), and curing the preliminary protective layer P-PM to form a protective layer PM (S230). FIGS. 9A and 9B schematically illustrate cross-sectional views of the step of applying of the first coating liquid CS to the bottom surface of the display panel DP to form the preliminary protective layer P-PM (S220). FIG. 9C schematically illustrates a cross-sectional view of the step of curing the preliminary protective layer P-PM to form the protective layer PM (S230).

The step of applying the first coating liquid CS to the bottom surface of the display panel DP to form the preliminary protective layer P-PM (S220) may be performed through an inkjet printing process or a dispenser process. However, an embodiment of the inventive concept is not limited thereto. Referring to FIG. 6 together, the protective layer PM according to an embodiment of the inventive concept may include a hole HH. Accordingly, the step of applying the first coating liquid CS to the bottom surface of the display panel DP (S220) may be performed through a process capable of forming a single hole HH or a plurality of holes HH in the preliminary protective layer P-PM. For example, applying the first coating liquid CS to the bottom surface of the display panel DP (S220) may be performed through a process capable of patterning.

The step of curing the preliminary protective layer P-PM to form the protective layer PM (S230) may include irradiating light LR onto the preliminary protective layer P-PM. The light LR may be ultraviolet (UV) light. As the preliminary protective layer P-PM is formed using the first coating liquid CS including a UV photocurable resin, the first coating liquid CS may be photocured by the UV light LR and form the protective layer PM.

Hereinafter, the results of evaluating the characteristic of a display device according to an embodiment of the inventive concept will be described with reference to the drawings set forth above, and with reference to an embodiment of the inventive concept and a comparative example described below. It should be noted that the embodiment described below is merely illustrative for facilitating understanding of the inventive concept, and the scope of the inventive concept is not limited thereto.

### Manufacture of Display Devices

The embodiment of the inventive concept and the comparative example were all manufactured using the same process except for a method of forming a protective layer PM. In the first Embodiment E1, the first particles were dispersed at about 0.05 wt % in a first coating liquid CS used for the protective layer PM, and the first particles were highly dispersed in a base resin by a first solvent. The average diameter of the first particles in the first Embodiment E1 was about 120 nm or less. The second Embodiment E2 was manufactured using the same method as the first Embodiment E1 except that about 0.1 wt % of the first particles were dispersed in the first coating liquid CS. In the first Comparative Example C1, the first particles were not included in the first coating liquid CS used for the protective layer PM. In the second Comparative Example C2, the first particles were dispersed at about 0.05 wt % in the first coating liquid CS used for the protective layer PM, and the first solvent was not used for the preparation and thus the first particles were lowly dispersed in the base resin. The average diameter of the first particles in the second Comparative Example C2 was more than about 120 nm. The third Comparative Example C3 was manufactured using the same method as the second Comparative Example C2 except that about 0.1 wt % of the first particles were dispersed in the first coating liquid. Since the first solvent was not used for the preparation and thus the first particles of the third Comparative Example C3 were lowly dispersed in the base resin.

### Evaluation of Display Devices

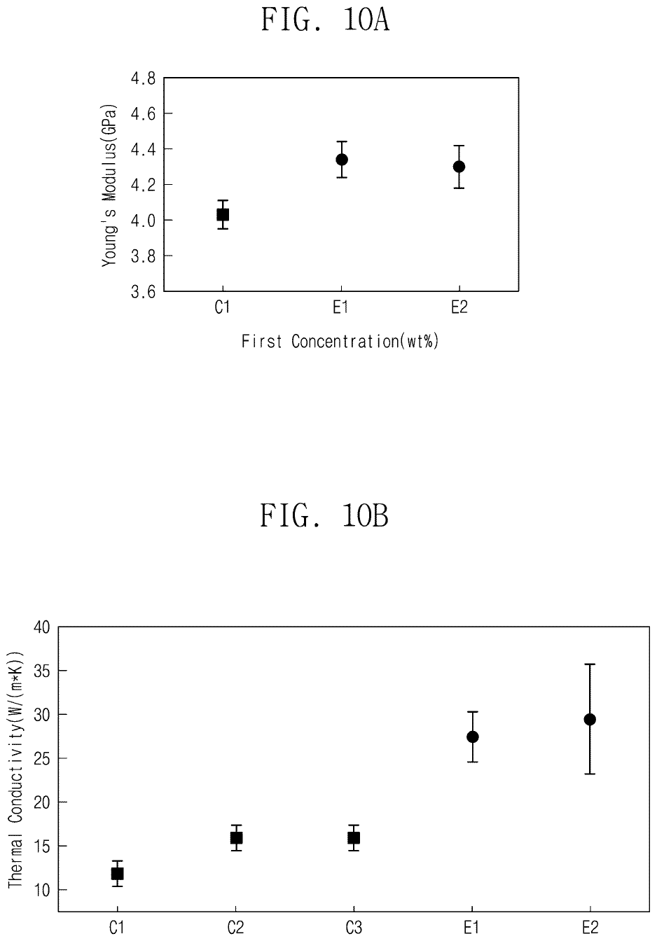

FIG. 10A illustrates Young's moduli of an embodiment of the inventive concept and a comparative example. FIG. 10B illustrates thermal conductivities of an embodiment of the inventive concept and a comparative example. The Young's moduli of the embodiment of the inventive concept and the comparative example shown in FIG. 10A were measured using a nano indentation tester. The thermal conductivities of the embodiment of the inventive concept and the comparative example shown in FIG. 10B were measured by first determining thermal diffusivities using an Angstrom method, and then calculating the thermal conductivities using the thermal conductivity calculation method based on specific heat and density of the protective layer PM.

Referring to FIG. 10A, the embodiment of the inventive concept shows higher Young's modulus values than the comparative example. Specifically, the protective layer PM according to an embodiment of the inventive concept has a Young's modulus value of about 4 Gpa to about 50 Gpa. In contrast, Comparative Example C1 has a Young's modulus value of about 4 Gpa or less and thus has relatively low modulus characteristic than the embodiment of the inventive concept. It is understood that compared to Comparative Example C1, Embodiments E1 and E2 include the first particles dispersed in the protective layer PM and thus have the high Young's modulus values. The display device DD according to an embodiment of the inventive concept may include the protective layer PM having the Young's modulus value in a range from about 4 Gpa to about 50 Gpa. Accordingly, even when the protective layer PM which has a single-layer structure is provided below the display panel DP, the protective layer PM may perform the function such as supporting panels, more than a certain level, thereby improving the reliability of the display device DD.

Referring to FIG. 10B, the embodiment of the inventive concept shows higher thermal conductivity values than the comparative example. Specifically, the protective layer PM according to an embodiment of the inventive concept has a thermal conductivity value of about 25 W/mK to about 300 W/mK. As explained above, Embodiments E1 and E2 of the inventive concept include the first particles dispersed in the protective layer PM and thus have high thermal conductivity values. In addition, as explained above, Comparative Examples C2 and C3 include the first particles in the protective layer PM in less dispersed manner than Embodiments E1 and E2 and the average diameter of the first particles are more than about 120 nm, thereby having relatively low thermal conductivity values. The display device according to an embodiment of the inventive concept may include the protective layer PM having the thermal conductivity value of about 25 W/mK to about 300 W/mK. Accordingly, even when the protective layer PM which has a single-layer structure is provided below the display panel DP, the protective layer PM may perform the functions such as heat dissipation and shielding, more than a certain level, thereby improving the reliability of the display device DD.

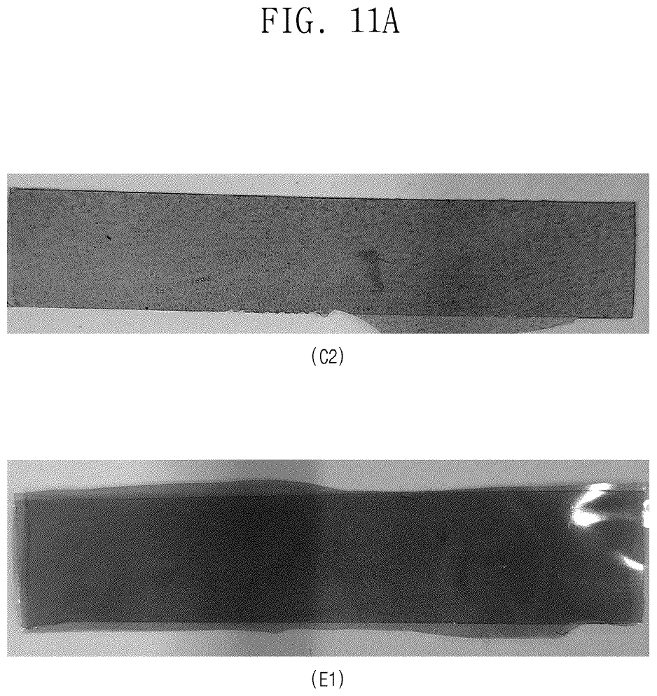

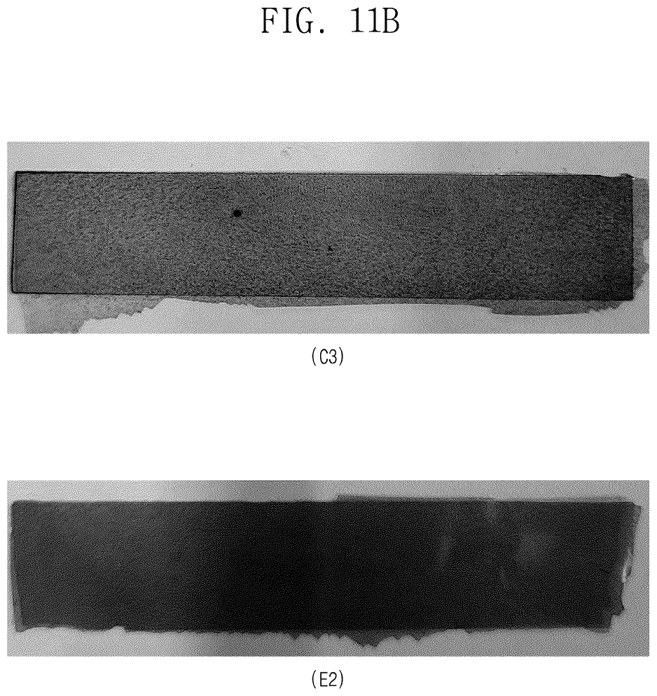

Each of FIG. 11A and FIG. 11B illustrates photographs of an embodiment of the inventive concept and a comparative example, arranged side by side. FIG. 11A illustrates photographs of the first Embodiment E1 in which about 0.05 wt % of the first particles were highly dispersed, and the second Comparative Example C2 in which about 0.05 wt % of the first particles were lowly dispersed. FIG. 11B illustrates photographs the second Embodiment E2 in which about 0.1 wt % of the first particles were highly dispersed, and the third Comparative Example C3 in which about 0.1 wt % of the first particles were lowly dispersed.

Referring to FIGS. 11A and 11B, the embodiment of the inventive concept shows a higher dispersity of the first particles in the first coating liquid CS than the comparative example. The protective layer PM may be manufactured using the first coating liquid CS prepared using the first particles having the higher dispersity, and thus the display device DD according to an embodiment of the inventive concept may have uniform absorbance characteristics on a plane. Even when the protective layer PM according to an embodiment of the inventive concept includes a reduced graphene oxide material, the reduced graphene oxide material may be highly dispersed in the base resin by the first solvent, and thus an aggregation phenomenon of graphene may not occur. Accordingly, the optical characteristics of the display device DD including the protective layer PM according to an embodiment of the inventive concept may be improved. Moreover, even when the protective layer PM according to an embodiment of the inventive concept includes the reduced graphene oxide material, the reduced graphene oxide material may be highly dispersed in the base resin by the first solvent, and thus the protective layer PM may include the first particles having the average diameter of about 120 nm or less. Accordingly, even when having a relatively thin thickness, the protective layer PM may perform various functions such as supporting, heat dissipation, and shielding.

In the display device according to the embodiment of the inventive concept and the electronic device including the same, the single protective layer including the first particles and the base resin may be arranged below the display panel, thereby having the uniform absorbance characteristics on a plane and, despite the relatively thin thickness, performing the various functions such as supporting, heat dissipation, and shielding.

In the above, description has been made with reference to embodiments of the inventive concept, but those skilled in the art or those of ordinary skill in the art will understand that various modifications and changes may be made to the inventive concept insofar as such modifications and changes do not depart from the spirit and technical feature of the inventive concept set forth in the claims to be described later.

Therefore, the technical scope of the inventive concept is not to be limited to the contents stated in the detailed description of the specification, but should be determined by the claims.

What is claimed is:

1. A display device comprising:
a display panel; and
a protective layer directly disposed below the display panel,
wherein the protective layer comprises a base resin and first particles dispersed in the base resin,
wherein each of the first particles comprises reduced graphene oxide, and
wherein a Young's modulus of the protective layer is in a range from about 4 Gpa to about 50 Gpa.

2. The display device of claim 1, wherein a thermal conductivity of the protective layer is in a range from about 25 W/mK to about 300 W/mK.

3. The display device of claim 1, wherein an average diameter of the first particles is in a range from about 50 nm to about 250 nm.

4. The display device of claim 1, wherein a ratio of a weight of the first particles to a total weight of the protective layer is in a range from about 0.05 wt % to about 30 wt %.

5. The display device of claim 1, wherein the base resin is a photocurable resin.

6. The display device of claim 1, wherein the base resin comprises one of solvent-free acryl-based resin, solvent-free urethane-based resin, solvent-free fluorine-based resin, solvent-free epoxy-based resin, solvent-free polyester-based resin, solvent-free polyamide-based resin, and solvent-free silicon-based resin.

7. The display device of claim 1, wherein a thickness of the protective layer is in a range from about 10 μm to about 300 μm.

8. The display device of claim 1, further comprising a circuit board electrically connected to the display panel,
wherein the protective layer is in contact with at least a portion of the circuit board.

9. An electronic device comprising:
a display device comprising a display panel;
a protective layer directly disposed below the display panel and including a hole accommodating an electronic module; and
a power module configured to supply power necessary for an operation of the display device,
wherein the protective layer comprises a base resin and first particles dispersed in the base resin,
wherein each of the first particles comprises reduced graphene oxide, and
wherein a Young's modulus of the protective layer is in a range from about 4 Gpa to about 50 Gpa.

10. The electronic device of claim 9, wherein the display panel comprises a first area and a second area adjacent to the first area, and
wherein the electronic module overlaps the first area and is disposed below the display panel.

11. The electronic device of claim 10, wherein the protective layer overlaps the second area.

12. The electronic device of claim 10, wherein the hole of the protective layer is arranged corresponding to the first area, and
wherein at least a portion of the electronic module is disposed inside the hole.

13. The electronic device of claim 12, wherein the electronic module includes a sensor module or a camera module.

14. A method of manufacturing a display device, the method comprising:
providing a display panel; and
forming a protective layer below the display panel,
wherein the step of forming the protective layer below the display panel comprises:
preparing a first coating liquid;
applying the first coating liquid to a bottom surface of the display panel to form a preliminary protective layer; and
curing the preliminary protective layer to form a protective layer, and
wherein the step of preparing the first coating liquid comprises:
mixing a first solvent with first particles to form a first mixture;
mixing the first mixture with a base resin to form a second mixture; and
evaporating the first solvent in the second mixture.

15. The method of claim 14, wherein the first solvent comprises one of methanol, ethanol, dimethylformamide, dimethylacetamide, N-methylpyrrolidone, and dimethylformamide.

16. The method of claim 14, wherein a dispersity of the first particles in the first solvent is higher than a dispersity of the first particles in the base resin.

17. The method of claim 14, wherein the step of forming the preliminary protective layer is performed through an inkjet printing process or a dispenser process.

18. The method of claim 14, wherein the step of curing the preliminary protective layer comprises irradiating light onto the preliminary protective layer to photocure the first coating liquid.

19. The method of claim 18, wherein the irradiated light is ultraviolet light.

20. The method of claim 14, wherein the step of evaporating the first solvent in the second mixture is performed at a temperature ranging from about 15° C. to about 25° C.
